(19) United States
(12) Patent Application Publication
(10) Pub. No.: US 2009/0243673 A1
(43) Pub. Date: Oct. 1, 2009

(54) PHASE LOCKED LOOP SYSTEM AND PHASE-LOCKING METHOD FOR PHASE LOCKED LOOP

(75) Inventor: Wei-Chun Lin, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NOVATEK MICROELECTRONICS CORP., Hsinchu (TW)

(21) Appl. No.: 12/171,302

(22) Filed: Jul. 11, 2008

(30) Foreign Application Priority Data
Mar. 27, 2008 (TW) 97111018

(51) Int. Cl. H03L 7/095

(52) U.S. Cl. 327/157; 327/159

(57) ABSTRACT

A PLL (phase locked loop) system includes a PLL and a lock detector. The PLL is for outputting a phase-locking clock signal. The lock detector is coupled to the PLL for detecting whether or not the frequency of the phase-locking clock signal falls within a predetermined frequency range and detecting whether or not the phase-locking clock signal is stable. If the frequency of the phase-locking clock signal has fallen within the predetermined frequency range and the phase-locking clock signal is stable by detection, the lock detector outputs a lock signal.

### CROSS-REFERENCE TO RELATED APPLICATION

This application claims the priority benefit of Taiwan application serial no. 97111018, filed on Mar. 27, 2008. The entirety of the above-mentioned patent application is hereby incorporated by reference herein and made a part of specification.

### BACKGROUND OF THE INVENTION

1. Field of the Invention

The present invention generally relates to a phase locked loop (PLL) technique, and more particularly, to a PLL system having accurately frequency-locking function.

2. Description of Related Art

Referring to the loop portion of FIG. 1, which shows a basic circuit of the PLL. The PLL mainly has two input terminals for respectively receiving a reference frequency serving as a reference clock signal Ref_CLK and receiving a feedback frequency. The feedback frequency is a feedback signal of the PLL, and the feedback signal is usually fed back, for example, after appropriately lowering the frequency thereof. The PLL includes a phase-frequency detector (PFD) 100 receiving the above-mentioned two input signals. The PFD 100 would compare the difference between the reference frequency and the feedback frequency, and detect the phase difference and the frequency difference between the reference frequency and the feedback frequency. When the reference frequency is higher than the feedback frequency, the PFD 100 would output a pulse signal from an output terminal UP thereof; in contrast, when the reference frequency is less than the feedback frequency, the PFD 100 would output another pulse signal from another output terminal DN thereof. The pulse signal generated by the PFD 100 then is sent to a charge pump 102 and a loop filter 104, where the pulse signal is converted into a voltage control signal for controlling a voltage controlled oscillator (VCO) 106 of the next stage. VCO 106 generates a clock signal VCO_CLK according to the voltage control signal. The clock signal VCO_CLK would be fed back to the PFD 100 so as to conduct a loop operation for phase-locking. However, the frequency of the clock signal VCO_CLK may need to be appropriately reduced by using a frequency divider 108 according to the operation frequency of the PFD 100, followed by being fed back to the PFD 100. The locking mechanism herein is, for example, to make the output clock signal VCO_CLK fed back to the PFD 100 so as to be synchronous with the reference frequency and to keep the identical phase and frequency states with the reference frequency.

In order to judge whether or not the PLL system has been properly locked by detecting, the conventional PLL system would include a lock detection circuit to detect the two output signals of the PFD 100 for thereby judging whether or not the reference frequency and the output frequency of the PLL have been locked. However, in the operation practice, the reference frequency input from the outside may be disappeared; when the input signal is disappeared, the output signals at the two terminals UP and DN of the PFD 100 would be disabled, which results in a false judgment of the lock detection circuit.

In short, a better mechanism is needed by the related manufactures for judging the locking state of a PLL system.

### SUMMARY OF THE INVENTION

Accordingly, the present invention is directed to a PLL system, a frequency-locked detector and a phase-locking method for a PLL, which in association with a lock detection circuit and a lock detection method based on a new mechanism are able to at least promote the locking accuracy.

The present invention provides a PLL system, which includes a PLL and a lock detector. The PLL is for outputting a phase-locked clock signal. The lock detector is coupled to the PLL for detecting whether or not the frequency of the phase-locked clock signal falls within a predetermined frequency range and whether or not the phase-locked clock signal is stable. If the frequency of the phase-locked clock signal falls within the predetermined frequency range and is stable by detection, the lock detector outputs a lock signal.

According to an embodiment of the present invention, in the said PLL, the lock detector includes: for example, a frequency discriminator coupled to the PLL for detecting whether or not the frequency of the phase-locked clock signal falls within the predetermined frequency range and thereby outputting a first detection result; a comparison unit used to judge whether or not the phase-locked clock signal is stable so as to output a second detection result; and a lock judging unit coupled to the frequency discriminator and the comparison unit for outputting a frequency locked state signal according to the first detection result and the second detection result.

According to an embodiment of the present invention, in the said PLL, the frequency discriminator is, for example, coupled to the comparison unit. In addition, the frequency discriminator also functions to convert the phase-locked clock signal into a frequency digital code signal and to output the frequency digital code signal to the comparison unit.

The comparison unit includes: a first shift register for receiving the frequency digital code signal; a digital comparator coupled to the first shift register for receiving the frequency digital code signal and the output of the first shift register, comparing the frequency digital code signal with the output of the first shift register to judge whether or not the said two signals are the same as each other, and thereby outputting a third detection result; and a judging unit coupled to the digital comparator for receiving a plurality of successive third detection results for judging whether or not the time numbers for the frequency digital code signal and the output of the first shift register to be the same are greater than a predetermined time number and thereby outputting the second detection result.

According to an embodiment of the present invention, in the said PLL, the judging unit is, for example, a second shift register for shifting and registering the third detection result. If, for example, among the plurality of third detection results, there is any one detection result indicating the frequency digital code signal is different from the output of the first shift register, the second shift register is reset.

According to an embodiment of the present invention, in the said PLL, the frequency discriminator, for example, sets the predetermined frequency range according to a frequency-setting signal.

According to an embodiment of the present invention, in the said PLL, the PLL includes: for example, a PFD for receiving a reference clock signal and a feedback signal and generating an output according to the reference clock signal and the feedback signal; a charge pump coupled to the PFD for receiving the outputs from the first level output terminal and the second level output terminal of the PFD; a loop filter coupled to the charge pump for receiving the output of the charge pump; a voltage controlled oscillator (VCO) coupled to the loop filter for receiving the output of the loop filter and generating the phase-locked clock signal; and a frequency divider for conducting frequency-dividing on the phase-locked clock signal and outputting the feedback signal after the frequency-dividing to the PFD.

The present invention also provides a frequency-locked detector, which includes a frequency discriminator, a comparison unit and a lock judging unit. The frequency discriminator is for detecting whether or not the frequency of a phase-locked clock signal falls within a predetermined frequency range and thereby outputting a first detection result. The comparison unit is used to judge whether or not the phase-locked clock signal is stable so as to output a second detection result. The lock judging unit is coupled to the frequency discriminator and the comparison unit for outputting a frequency locked state signal according to the first detection result and the second detection result.

According to an embodiment of the present invention, in the said frequency-locked detector, the frequency discriminator is coupled to the comparison unit. The frequency discriminator further converts the phase-locked clock signal into a frequency digital code signal and outputs the frequency digital code signal to the comparison unit.

The comparison unit includes, for example, a first shift register, a digital comparator and a judging unit. The first shift register is for receiving the frequency digital code signal. The digital comparator is coupled to the first shift register for receiving the frequency digital code signal and the output of the first shift register, comparing the frequency digital code signal with the output of the first shift register to judge whether or not the said two signals are the same as each other, and thereby outputting a third detection result. The judging unit is coupled to the digital comparator for receiving a plurality of successive third detection results to judge whether or not the time numbers for the frequency digital code signal and the output of the first shift register to be the same are greater than a predetermined time number and thereby outputting the second detection result.

According to an embodiment of the present invention, in the said frequency-locked detector, the judging unit is, for example, a second shift register for shifting and registering the third detection result. If, for example, among the plurality of third detection results, there is any one detection result indicating the frequency digital code signal is different from the output of the first shift register, the second shift register is reset.

According to an embodiment of the present invention, in the said frequency-locked detector, the frequency discriminator, for example, sets the predetermined frequency range according to a frequency-setting signal.

The present invention also provides a phase-locking method for a PLL. The method includes obtaining a phase-locked clock signal to be output by a PLL; detecting whether or not the phase-locked clock signal falls within a predetermined frequency range; detecting whether or not the phase-locked clock signal is stable; and if the frequency of the phase-locked clock signal falls within the predetermined frequency range and the phase-locked clock signal is stable by detection, outputting a lock signal.

According to an embodiment of the present invention, in the said phase-locking method for a PLL, for example, the step of detecting whether or not the phase-locked clock signal is stable includes generating a frequency digital code signal corresponding to the phase-locked clock signal; receiving the frequency digital code signal and an operation clock signal by using a first shift register; receiving the operation clock signal and the output of the first shift register by using a digital comparator; comparing the frequency digital code signal at a previous time point with the frequency digital code signal at the time point next to the previous time point to judge whether or not the two frequency digital code signals are the same; if the two frequency digital code signals are the same, outputting a signal; receiving the operation clock signal and the output signal of the digital comparator by using a second shift register and outputting a logic state signal after a decision.

According to an embodiment of the present invention, in the said phase-locking method for a PLL, for example, a frequency discriminator is used to generate the frequency digital code signal.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a PLL according to an embodiment of the present invention.

FIG. 2A is a schematic graph showing a proper frequency signal output during operating a PLL.

FIG. 2B is a schematic graph showing an improper frequency signal output during operating a PLL.

FIG. 3 is a circuit diagram of a PLL according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In a PLL system of the present invention, a frequency discriminator is employed and the frequency output from the PLL is input to the frequency discriminator. The frequency discriminator converts a received phase-locked clock signal into a digital code and registers the digital code. When the above-mentioned frequency falls within a frequency window for the frequencies to be locked, the registered digital code is compared with the just-converted digital code, which is equivalent to a comparison between a last phase-locked clock signal and the newly received phase-locked clock signal. If the above-mentioned two phase-locked clock signals continuously keep the same as each other, a frequency lock state can be precisely obtained.

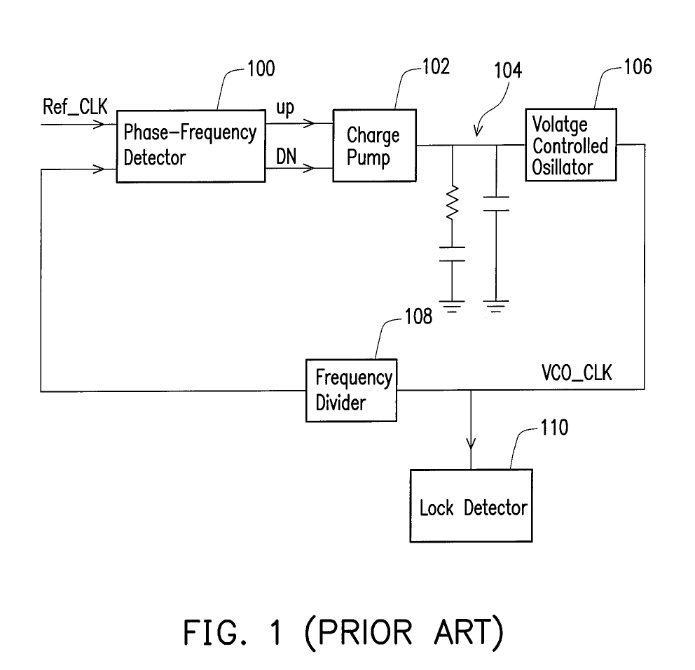

FIG. 1 is a circuit diagram of a PLL according to an embodiment of the present invention. Referring to FIG. 1, the PLL in the PLL system herein may be a PLL in usual design, to which the present invention is not necessary to limit. As described hereinbefore, a basic PLL includes, for example, a PFD 100, a current controller 102, a filter 104 and a VCO 106. In addition, if needed, the PLL can employ an additional frequency divider 108 on the feedback path.

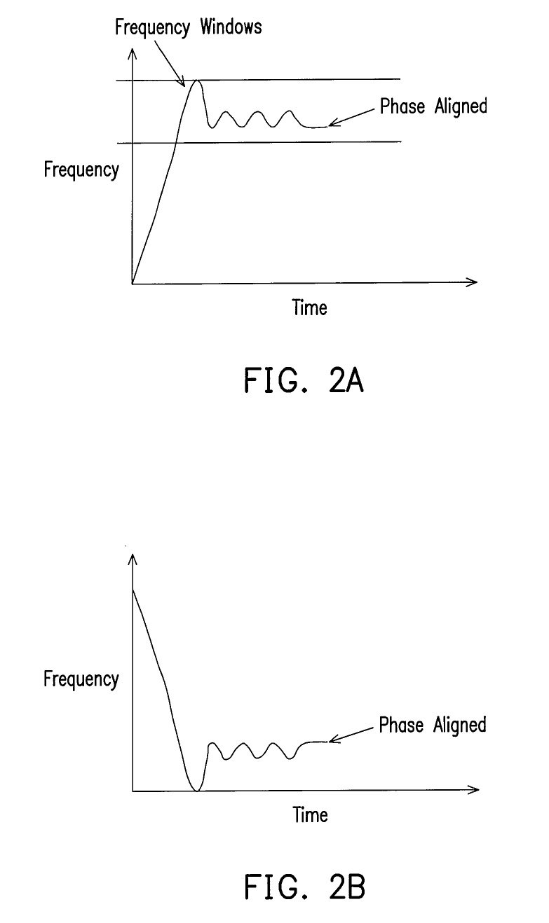

Note that the phase-locking function of the PLL includes not only locking and aligning the phase of a phase-locked clock signal to be output, but also locking the frequency of the phase-locked clock signal within a desired frequency range. FIG. 2A is a schematic graph showing a proper frequency signal output during operating a PLL. Referring to FIG. 2A, a frequency to be output by the PLL is able to tend to a stable and phase-aligned frequency after a certain period of fluctuation due to a negative feedback mechanism. If the frequency falls within a frequency window (that is, the above-mentioned frequency range), it means the frequency to be output has been properly locked within the desired phase-frequency range.

FIG. 2B is a schematic graph showing an improper frequency signal output during operating a PLL. Referring to FIG. 2B, in the prior art, whether the frequency is properly locked is decided by detection only according to outputs from the high level terminal UP and the low level terminal DN of the PLL; therefore, even a reference clock signal Ref_CLK is interrupted or changed, the PLL still can obtain a frequency with an aligned phase, but the obtained frequency is not the desired one.

On the other hand, the conventional lock detection scheme is to detect the high/low signals UP/DN output from a PFD. With the above-mentioned scheme to judge a PLL state, an extra capacitor is usually required, so that the capacitor would be charged with a phase error caused by the UP/DN signals through a constant current source. Meanwhile, a comparator on another path is used to judge the capacitor charged-state. When the capacitor is charged to a fixed voltage level, the output from the comparator would indicate whether the PLL is locked or not. The conventional scheme is indeed unable to precisely give a real locked position out.

The present invention provides an altered novel design of a PLL system, where a lock detector is used to directly judge the phase-locked clock signal output from the PLL. In the circuit block diagram of FIG. 1, a lock detector 110 receives a phase-locked clock signal VCO_CLK output from the VCO 106 of the PLL. The lock detector 110 detects whether the phase-locked clock signal falls within a desired frequency range and the phase-locked clock signal is stable. When both detections are both met, it is certain that the PLL has precisely locked the reference signal and the output phase-locked clock signal falls within the desired frequency range.

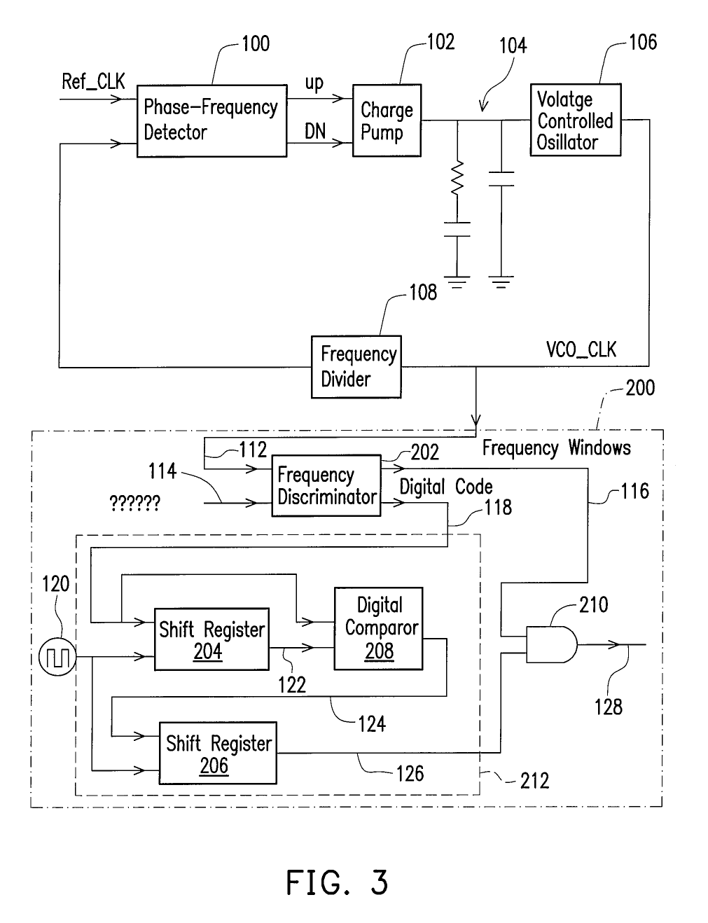

FIG. 3 is a circuit diagram of a PLL system according to an embodiment of the present invention. Referring to FIG. 3, the PLL system includes a PLL and a lock detector 200. As describe before, the PLL outputs a phase-locked clock signal, for example, a clock signal VCO_CLK output from the VCO 106. When the clock signal VCO_CLK reaches phase-aligned state, the PLL can be considered to be locked. However, the above-mentioned lock state does not ensure that the output phase-locked clock signal is definitely correct (i.e., the locked frequency may be incorrect); that is to say, the PLL may be at an error lock state.

The lock detector 200 in FIG. 3 is used to detect whether the PLL is in a proper phase locked state. In the embodiment, the lock detector 200 receives a phase-locked clock signal 112 output from the VCO 106 and a frequency-setting signal 114. The frequency-setting signal 114 is for setting a desired frequency range, and the setting can be done by using a register so as to decide a frequency (or a frequency range) to be locked. Note that the lock detector 200 is in charge of detecting whether or not a phase-locked clock signal has met the requirement of the desired frequency, but also in charge of detecting whether or not the phase-locked clock signal is stable and outputting a lock signal 128 when both detections are positive.

In more detail, the lock detector 200 includes, for example, a frequency discriminator 202, which sets a desired frequency range (for example, the above-mentioned frequency window) according to a received frequency-setting signal 114 and detects whether or not the phase-locked clock signal 112 falls within the frequency range so as to generate a detection signal 116. A judging signal herein is used to indicate whether the phase-locked clock signal 112 falls within the frequency range. In the embodiment, if the judging signal indicates the phase-locked clock signal 112 has fallen within the frequency range, the detection signal 116 is at logic value ‘1’; otherwise, at logic value ‘0’. Note that in the embodiment of FIG. 3, the frequency discriminator 202 is shown as a functional block diagram. Please note, the actual circuit for achieving these functions (e.g.: the detecting function) may be integrated into the frequency discriminator 202 or disposed outside the frequency discriminator 202. That is, the present invention mainly focuses on the function of the frequency discriminator, and does not limit the actual implementation of the circuit of the frequency discriminator. It can be designed individually. In other words, the present invention cover all architectures of the frequency discriminator 202, which can be used to achieve the above-mentioned detection mechanism.

The data of the detection signal 116 only represents the phase-locked clock signal 112 is in the required frequency range, but the phase-locked clock signal 112 may be not locked yet. In other words, the phase-locked clock signal 112 may not reach a phase-aligned state. Thus, the lock detector 200 needs further to detect whether the phase-locked clock signal 112 is stable. In the embodiment, the present invention also employs a comparison unit 212 for detecting whether the phase-locked clock signal 112 is stable. In addition, the frequency discriminator 202 would detect the phase-locked clock signal 112 at several predetermined time points. Meanwhile, for example, a counter can be used to convert the phase-locked clock signal 112 into a corresponding digital code 118, so that a corresponding digital code 118 is output at the above-mentioned predetermined time points.

In terms of the mechanism, since the phase-locked clock signal 112 would theoretically be converged to a stable frequency and the corresponding digital code 118 would become a fixed value as well; i.e., if the phase-locked clock signal output from the PLL gets stable already, the digital codes 118 at a current time point and a previous time point would be the same. Therefore, the present invention utilizes the above-mentioned theory to perform the detection.

In the embodiment, the comparison unit 212 is implemented by using two shift registers 204 and 206 and a digital comparator 208. The shift register 204 receives an operation clock signal 120 and a digital code 118. The digital comparator 208 meanwhile also receives the digital code 118. The shift register 204 buffers the digital code 118 and outputs the code according to a timing sequence. The output digital codes 118 are compared by a multi-bit digital comparator 208, for example, the digital code 118 at the current time point and the digital code 118 at the previous time point are compared. If the two digital codes are the same, a high-level signal 124 is output for enabling the shift register 206 of the next stage. Note that the two digital codes can be substantially the same, this means that in some circumstances a margin between the two digital codes are allowed without being absolute equal to each other.

The shift register 206 operates as follows. If the outputs of the digital comparator 208 durably keep at a high level in several clocks, a high-level detection signal 126 (corresponding to logic value ‘1’) is output. The number of the clocks to be compared is determined by a real application, which can be two or more, and the situation of more clocks means that the signal is more stable. Besides, among the clocks, if there is any one among a plurality of detection signals 126 corresponding to logic value ‘0’ (i.e., a digital code at a time point is different from the digital code at the last time point), the shift register 206 would be reset and re-detect whether the phase-locked clock signal 112 is in a lock state.

The shift register 206 can include a false lock detector circuit. When the outputs of the digital comparator 208 keep to be low-level clocks, it means that the phase-locked clock signal is in false lock state, so the shift register 206 must be reset and another phase alignment needs to be started for changing the state.

If both the detection signals 116 and 126 are corresponding to logic value ‘1’ (logic-true state), which indicates the phase-locked clock signal is not only within the correct frequency range, but also enters lock state. The logic unit 210 conducts judging, and, for example, an AND gate is used for the judging, wherein only two signals 116 and 126 take logic-true state, a logic-true signal can be output, which means that the output clock signal is in phase-locked state.

The embodiments provided by the present invention can increase the accuracy of lock state, but the present invention is not limited to the above-described embodiments.

The above described are preferred embodiments of the present invention only, which do not limit the implementation scope of the present invention. It will be apparent to those skilled in the art that various modifications and equivalent variations can be made to the structure of the present invention without departing from the scope or spirit of the invention.

What is claimed is:

1. A phase locked loop system, comprising:
a phase locked loop for outputting a phase-locked clock signal; and
a lock detector, coupled to the phase locked loop for detecting whether a frequency of the phase-locked clock signal falls within a predetermined frequency range, detecting whether the phase-locked clock signal is stable, and outputting a lock signal if detecting that the frequency of the phase-locked clock signal falls within the predetermined frequency range and the phase-locked clock signal is stable.

2. The phase locked loop system according to claim 1, wherein the lock detector comprises:
a frequency discriminator, coupled to the phase locked loop for detecting whether the frequency of the phase-locked clock signal falls within the predetermined frequency range and thereby outputting a first detection result;
a comparison unit, for determining whether the phase-locked clock signal is stable so as to output a second detection result; and
a lock judging unit, coupled to the frequency discriminator and the comparison unit for outputting a frequency locked state signal according to the first detection result and the second detection result.

3. The phase locked loop system according to claim 2, wherein the frequency discriminator is coupled to the comparison unit, the frequency discriminator further converts the phase-locked clock signal into a frequency digital code signal and outputs the frequency digital code signal to the comparison unit, and the comparison unit comprises:
a first shift register for receiving the frequency digital code signal;
a digital comparator, coupled to the first shift register for receiving the frequency digital code signal and an output of the first shift register, comparing the frequency digital code signal with the output of the first shift register to judge whether the frequency digital code signal is the same as the output of the first shift register, and thereby outputting a third detection result; and
a judging unit, coupled to the digital comparator for receiving a plurality of successive third detection results for judging whether a counting number for the frequency digital code signal and the output of the first shift register to be the same is greater than a predetermined counting number and thereby outputting the second detection result.

4. The phase locked loop system according to claim 3, wherein, the judging unit is a second shift register for shifting and registering the third detection result.

5. The phase locked loop system according to claim 4, wherein if among the plurality of third detection results, there is any one detection result indicating that the frequency digital code signal and the output of the first shift register are different, the second shift register is reset.

6. The phase locked loop system according to claim 1, wherein the frequency discriminator sets the predetermined frequency range according to a frequency-setting signal.

7. The phase locked loop system according to claim 1, wherein the phase locked loop comprises:
a phase-frequency detector for receiving a reference clock signal and a feedback signal and generating an output according to the reference clock signal and the feedback signal;
a charge pump, coupled to the phase-frequency detector for receiving the outputs from the first level output terminal and the second level output terminal of the phase-frequency detector;
a loop filter, coupled to the charge pump for receiving the output of the charge pump;
a voltage controlled oscillator, coupled to the loop filter for receiving the output of the loop filter and generating the phase-locked clock signal; and
a frequency divider for conducting frequency-dividing on the phase-locked clock signal and outputting the feedback signal to the phase-frequency detector after dividing the frequency of the phase-locked clock signal.

8. A frequency-locked detector, comprising:
a frequency discriminator for detecting whether the frequency of a phase-locked clock signal falls within a predetermined frequency range and thereby outputting a first detection result;
a comparison unit for judging whether the phase-locked clock signal is stable so as to output a second detection result; and
a lock judging unit, coupled to the frequency discriminator and the comparison unit for outputting a frequency locked state signal according to the first detection result and the second detection result.

9. The frequency-locked detector according to claim 8, wherein the frequency discriminator is coupled to the comparison unit; the frequency discriminator further converts the phase-locked clock signal into a frequency digital code signal and outputs the frequency digital code signal to the comparison unit, wherein the comparison unit comprises:
a first shift register for receiving the frequency digital code signal;
a digital comparator, coupled to the first shift register for receiving the frequency digital code signal and an output of the first shift register, comparing the frequency digital code signal with the output of the first shift register to judge whether the frequency digital code signal is the same as the output of the first shift register, and accordingly outputting a third detection result; and
a judging unit, coupled to the digital comparator for receiving a plurality of successive third detection results to judge whether a counting number for the frequency digital code signal and the output of the first shift register to be the same is greater than a predetermined counting number and accordingly outputting the second detection result.

10. The frequency-locked detector according to claim 9, wherein the judging unit is a second shift register for shifting and registering the third detection result.

11. The frequency-locked detector according to claim 10, wherein among the plurality of third detection results, if there is any one detection result indicating the frequency digital code signal is different from the output of the first shift register, the second shift register is reset.

12. The frequency-locked detector according to claim 8, wherein, the frequency discriminator sets the predetermined frequency range according to a frequency-setting signal.

13. A phase-locking method for a phase locked loop, comprising:
obtaining a phase-locked clock signal to be output by a phase locked loop;
detecting whether a frequency of the phase-locked clock signal falls within a predetermined frequency range; and
detecting whether the phase-locked clock signal is stable; and outputting a lock signal if the frequency of the phase-locked clock signal falls within the predetermined frequency range and the phase-locked clock signal is stable by detection.

14. The phase-locking method for a phase locked loop according to claim 13, wherein the step of detecting whether the phase-locked clock signal is stable comprises:
generating a frequency digital code signal corresponding to the phase-locked clock signal;
receiving the frequency digital code signal and an operation clock signal by using a first shift register;
receiving the operation clock signal and the output of the first shift register and comparing the frequency digital code signal at a previous time point with the frequency digital code signal at the time point next to the previous time point to judge whether the two frequency digital code signals are the same by using a digital comparator;
if the two frequency digital code signals are the same, outputting a signal; and
receiving the operation clock signal and the output signal of the digital comparator by using a second shift register and outputting a logic state signal according to the operation clock signal and the signal output from the digital comparator.

15. The phase-locking method for a phase locked loop according to claim 14, further comprising:
utilizing a frequency discriminator to generate the frequency digital code signal.
